(19) United States
(12) Patent Application Publication
(10) Pub. No.: US 2024/0312883 A1
(43) Pub. Date: Sep. 19, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Kelvin Hadinata WIBOWO, Kyoto (JP)

(21) Appl. No.: 18/603,628

(22) Filed: Mar. 13, 2024

(30) Foreign Application Priority Data
Mar. 16, 2023 (JP) 2023-041589

(51) Int. Cl. H01L 23/495; H01L 21/56; H01L 23/00; H01L 23/31

(52) U.S. Cl. CPC H01L 23/49582; H01L 21/56; H01L 23/3107; H01L 23/49555; H01L 24/32; H01L 24/33; H01L 24/83; H01L 2224/32245; H01L 2224/33181; H01L 2224/83

(57) ABSTRACT

A semiconductor device includes: a first terminal; a semiconductor element electrically connected to the first terminal; a sealing resin that covers the semiconductor element; and a protective layer that covers a portion of the first terminal and has conductivity, wherein the first terminal includes a first inner portion at least partially covered with the sealing resin, and a first outer portion connected to the first inner portion and protruding from the sealing resin, wherein the protective layer covers at least a portion of the first outer portion, wherein the first outer portion includes a first end surface facing in a first direction, and wherein the protective layer entirely covers the first end surface.

### CROSS-REFERENCE TO RELATED APPLICATION

This application is based upon and claims the benefit of priority from Japanese Patent Application No. 2023-041589, filed on Mar. 16, 2023, the entire contents of which are incorporated herein by reference.

### TECHNICAL FIELD

The present disclosure relates to a semiconductor device and a method of manufacturing the same.

### BACKGROUND

In the related art, an example of a semiconductor device including a first lead, a second lead, a semiconductor element conductively bonded to the first lead and the second lead, and a sealing resin that covers the semiconductor element is disclosed. The second lead mounts the semiconductor element. A portion of each of the first lead and the second lead is exposed from the sealing resin. The portion of each of the first lead and the second lead exposed from the sealing resin is covered with an exterior plating layer. The exterior plating layer contains tin. As a result, solder easily adapts to the portion of each of the first lead and the second lead exposed from the sealing resin while the semiconductor device is being mounted on a wiring board. As a result, it is possible to increase a contact area of each of the first lead and the second lead to the solder.

However, in the semiconductor device disclosed in the related art, an end surface facing a first direction of each of the first lead and the second lead exposed from the sealing resin is not covered with the exterior plating layer. Therefore, when the semiconductor device is mounted on the wiring board, the solder is less likely to creep up on the end surface of each of the first lead and the second lead. Therefore, in the semiconductor device, it is difficult to further increase the contact area of each of the first lead and the second lead to the solder.

### BRIEF DESCRIPTION OF DRAWINGS

The accompanying drawings, which are incorporated in and constitute a part of the specification, illustrate embodiments of the present disclosure.

FIG. 1 is a plan view of a semiconductor device according to a first embodiment of the present disclosure.

FIG. 2 is a plan view corresponding to FIG. 1, with a sealing resin being transparent.

FIG. 3 is a right side view of the semiconductor device shown in FIG. 1.

FIG. 4 is a left side view of the semiconductor device shown in FIG. 1.

FIG. 5 is a front view of the semiconductor device shown in FIG. 1.

FIG. 6 is a cross-sectional view taken along line VI-VI in FIG. 1.

FIG. 7 is a cross-sectional view taken along line VII-VII in FIG. 1.

FIG. 8 is a cross-sectional view taken along line VIII-VIII in FIG. 1.

FIG. 9 is a plan view illustrating a process of manufacturing the semiconductor device shown in FIG. 1.

FIG. 10 is a cross-sectional view taken along line X-X in FIG. 9.

FIG. 11 is a plan view illustrating a process of manufacturing the semiconductor device shown in FIG. 1.

FIG. 12 is a cross-sectional view taken along line XII-XII in FIG. 11.

FIG. 13 is a plan view illustrating a process of manufacturing the semiconductor device shown in FIG. 1.

FIG. 14 is a cross-sectional view taken along line XIV-XIV in FIG. 13.

FIG. 15 is a plan view illustrating a process of manufacturing the semiconductor device shown in FIG. 1.

FIG. 16 is a cross-sectional view taken along line XVI-XVI in FIG. 15.

FIG. 17 is a cross-sectional view illustrating a process of manufacturing the semiconductor device shown in FIG. 1.

FIG. 18 is a plan view of a semiconductor device according to a second embodiment of the present disclosure.

FIG. 19 is a plan view corresponding to FIG. 18, with a sealing resin being transparent.

FIG. 20 is a right side view of the semiconductor device shown in FIG. 18.

FIG. 21 is a left side view of the semiconductor device shown in FIG. 18.

FIG. 22 is a cross-sectional view taken along line XXII-XXII in FIG. 18.

FIG. 23 is a plan view of a semiconductor device according to a third embodiment of the present disclosure.

FIG. 24 is a plan view corresponding to FIG. 23, with a sealing resin being transparent.

FIG. 25 is a right side view of the semiconductor device shown in FIG. 23.

FIG. 26 is a left side view of the semiconductor device shown in FIG. 23.

FIG. 27 is a cross-sectional view taken along line XXVII-XXVII in FIG. 23.

FIG. 28 is a plan view illustrating a process of manufacturing the semiconductor device shown in FIG. 23.

FIG. 29 is a plan view illustrating a process of manufacturing the semiconductor device shown in FIG. 23.

FIG. 30 is a plan view of a semiconductor device according to a fourth embodiment of the present disclosure.

FIG. 31 is a plan view corresponding to FIG. 30, with a sealing resin being transparent.

FIG. 32 is a right side view of the semiconductor device shown in FIG. 30.

FIG. 33 is a left side view of the semiconductor device shown in FIG. 30.

FIG. 34 is a bottom view of the semiconductor device shown in FIG. 30.

FIG. 35 is a cross-sectional view taken along line XXXV-XXXV in FIG. 30.

FIG. 36 is a cross-sectional view taken along line XXXVI-XXXVI in FIG. 30.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments for carrying out the present disclosure will be described with reference to the accompanying drawings.

### First Embodiment

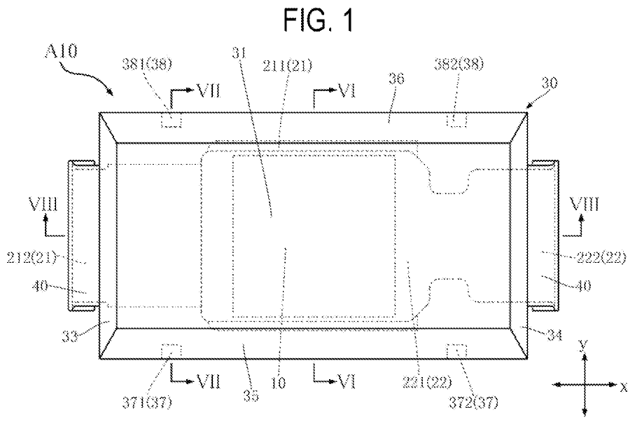

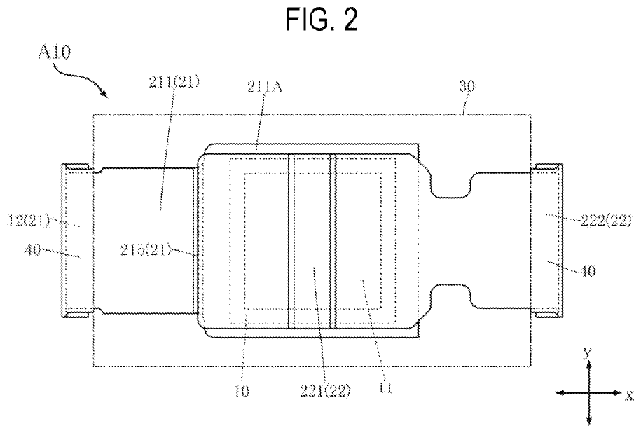

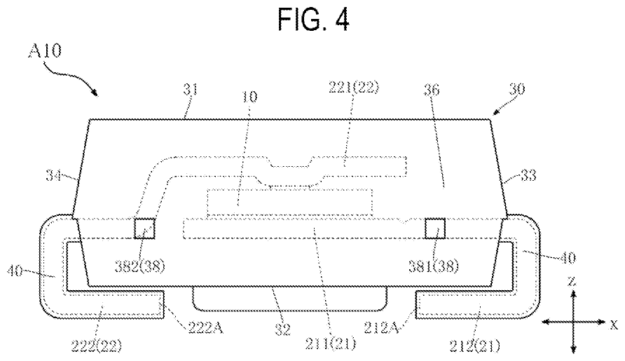

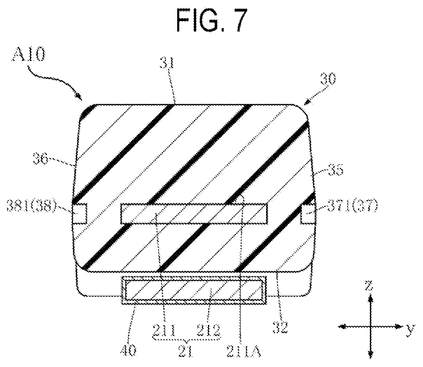

A semiconductor device A10 according to a first embodiment of the present disclosure will be described with reference to FIGS. 1 to 8. The semiconductor device A10 includes a semiconductor element 10, a first terminal 21, a second terminal 22, a sealing resin 30, and a protective layer 40. The semiconductor device A10 is in a form of a resin package that is surface-mounted on a wiring board. Here, in FIG. 2, for the sake of convenience of understanding, the sealing resin 30 is shown to be transparent. In FIG. 2, the sealing resin 30 is indicated by an imaginary line (two-dot chain line).

In the description of the semiconductor device A10, for the sake of convenience, a direction in which each of a first side surface 33 and a second side surface 34 of the sealing resin 30, which will be described later, faces, is referred to as a “first direction x.” A direction perpendicular to the first direction x is referred to as a “second direction y.” A direction perpendicular to both the first direction x and the second direction y is referred to as a “third direction z.” The third direction z corresponds to a normal direction of a mounting surface 211A of a first inner portion 211 of the first terminal 21, which will be described later.

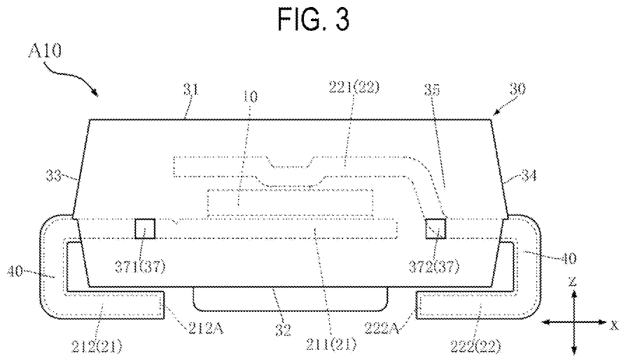

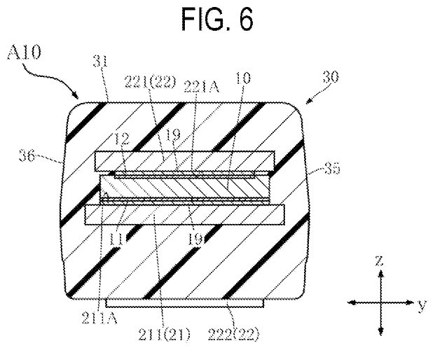

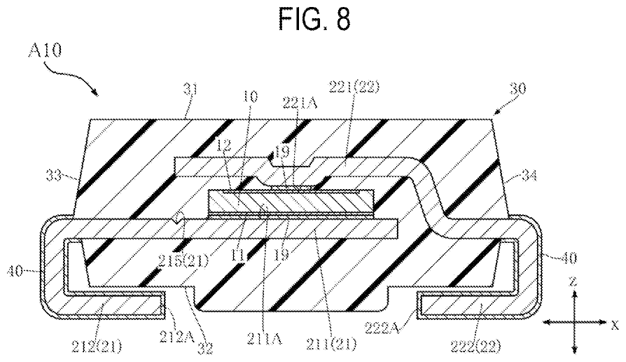

The sealing resin 30 covers the semiconductor element 10 and a portion of each of the first terminal 21 and the second terminal 22, as shown in FIGS. 6 and 8. The sealing resin 30 possesses an electrical insulation property. The sealing resin 30 is made of a material containing, for example, a black epoxy resin. As shown in FIGS. 3 to 5, the sealing resin 30 includes a top surface 31, a bottom surface 32, the first side surface 33, the second side surface 34, a third side surface 35, and a fourth side surface 36.

As shown in FIG. 8, the top surface 31 faces a same side in the third direction z as the mounting surface 211A of the first inner portion 211 of the first terminal 21, which will be described later. The bottom surface 32 faces an opposite side from the top surface 31 in the third direction z.

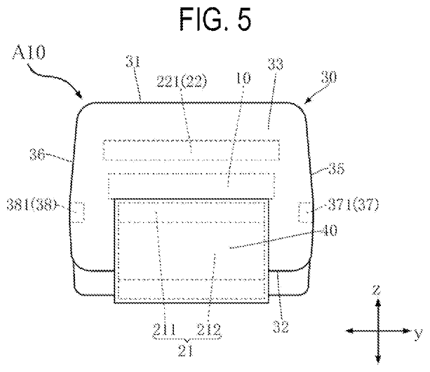

As shown in FIGS. 1, 3, and 4, the first side surface 33 and the second side surface 34 face opposite from each other in the first direction x. As shown in FIGS. 1 and 5, the third side surface 35 and the fourth side surface 36 face opposite from each other in the second direction y. Each of the first side surface 33, the second side surface 34, the third side surface 35, and the fourth side surface 36 is connected to the top surface 31 and the bottom surface 32.

The semiconductor element 10 is mounted on the first terminal 21, as shown in FIGS. 6 and 8. The semiconductor element 10 is electrically connected to each of the first terminal 21 and the second terminal 22. In the semiconductor device A10, the semiconductor element 10 is a Schottky barrier diode. Further, the semiconductor element 10 may include various elements such as a diode other than the Schottky barrier diode, a transistor, or the like.

The semiconductor element 10 includes a first electrode 11 and a second electrode 12. The first electrode 11 and the second electrode 12 are located opposite from each other in the third direction z. The first electrode 11 is electrically connected to the first terminal 21. The second electrode 12 is electrically connected to the second terminal 22. The first terminal 21 is a cathode. The second terminal 22 is an anode. The second electrode 12 is, for example, one in which a nickel (Ni) layer and a palladium (Pd) layer are stacked in this order on an aluminum (Al) layer. In the semiconductor device A10, a Schottky barrier is formed by interposing a metal thin film between a semiconductor layer constituting the semiconductor element 10 and the second electrode 12. The metal thin film includes, for example, molybdenum (Mo) or titanium (Ti).

Each of the first terminal 21 and the second terminal 22 forms a conductive path between the semiconductor element 10 and the wiring board on which the semiconductor device A10 is mounted. The first terminal 21 and the second terminal 22 are obtained from a same lead frame 80 (details of which will be described later). Each of the first terminal 21 and the second terminal 22 contains copper (Cu).

As shown in FIG. 1, the first terminal 21 is spaced apart from each of the third side surface 35 and the fourth side surface 36 of the sealing resin 30. As shown in FIGS. 1, 2, and 8, the first terminal 21 includes the first inner portion 211 and a first outer portion 212. At least a portion of the first inner portion 211 is covered with the sealing resin 30. In the semiconductor device A10, the first inner portion 211 is entirely covered with the sealing resin 30. The first inner portion 211 includes the mounting surface 211A facing the third direction z. The mounting surface 211A faces the first electrode 11 of the semiconductor element 10. The first electrode 11 is conductively bonded to the mounting surface 211A via a bonding layer 19. The bonding layer 19 is, for example, solder. As a result, the first electrode 11 is electrically connected to the first terminal 21. The first outer portion 212 is connected to the first inner portion 211. The first outer portion 212 protrudes from the first side surface 33 of the sealing resin 30. In the semiconductor device A10, the first outer portion 212 is bent around the second direction y along the first side surface 33 and the bottom surface 32 of the sealing resin 30. The first outer portion 212 includes a first end surface 212A facing in the first direction x. The first end surface 212A faces an opposite side from the first side surface 33 in the first direction x.

As shown in FIGS. 2 and 8, a groove portion 215 is formed at the first inner portion 211. The groove portion 215 is recessed from the mounting surface 211A of the first inner portion 211 in the third direction z. The groove portion 215 extends in the second direction y. The groove portion 215 is spaced apart from the semiconductor element 10 when viewed in the third direction z. A portion of the sealing resin 30 enters the groove portion 215.

As shown in FIG. 1, the second terminal 22 is spaced apart from each of the third side surface 35 and the fourth side surface 36 of the sealing resin 30. As shown in FIGS. 1, 2, and 8, the second terminal 22 includes a second inner portion 221 and a second outer portion 222. The second inner portion 221 is covered with the sealing resin 30. The second inner portion 221 includes a bonding surface 221A facing the third direction z. The bonding surface 221A faces the second electrode 12 of the semiconductor element 10. The bonding surface 221A is conductively bonded to the second electrode 12 via the bonding layer 19. As a result, the second electrode 12 is electrically connected to the second terminal 22.

The second outer portion 222 is connected to the second inner portion 221. The second outer portion 222 protrudes from the second side surface 34 of the sealing resin 30. In the semiconductor device A10, the second outer portion 222 is bent around the second direction y along the second side surface 34 and the bottom surface 32 of the sealing resin 30. The second outer portion 222 includes a second end surface 222A facing in the first direction x. The second end surface 222A faces an opposite side from the second side surface 34 in the first direction x. Further, the second end surface 222A faces an opposite side from the first end surface 212A of the first outer portion 212 of the first terminal 21 in the first direction x.

As shown in FIGS. 1, 3, and 7, a first concave portion 37 recessed from the third side surface 35 is formed in the sealing resin 30. The first concave portion 37 includes a first portion 371 and a second portion 372 that are spaced apart from each other in the first direction x. The first portion 371 overlaps the first inner portion 211 of the first terminal 21 when viewed in the second direction y. The second portion 372 overlaps the second inner portion 221 of the second terminal 22.

As shown in FIGS. 1, 4, and 7, a second concave portion 38 recessed from the fourth side surface 36 is formed in the sealing resin 30. The second concave portion 38 overlaps the first concave portion 37 when viewed in the second direction y. The second concave portion 38 includes a third portion 381 and a fourth portion 382 that are spaced apart from each other in the first direction x. The third portion 381 overlaps the first inner portion 211 of the first terminal 21 when viewed in the second direction y. The fourth portion 382 overlaps the second inner portion 221 of the second terminal 22.

The protective layer 40 covers a portion of each of the first terminal 21 and the second terminal 22. The protective layer 40 possesses electrical conductivity. The protective layer 40 is metal containing, for example, tin (Sn). The protective layer 40 covers at least a portion of the first outer portion 212 of the first terminal 21 and at least a portion of the second outer portion 222 of the second terminal 22. The protective layer 40 entirely covers the first end surface 212A of the first outer portion 212 and the second end surface 222A of the second outer portion 222. In the semiconductor device A10, the protective layer 40 covers the entirety of each of the first outer portion 212 and the second outer portion 222.

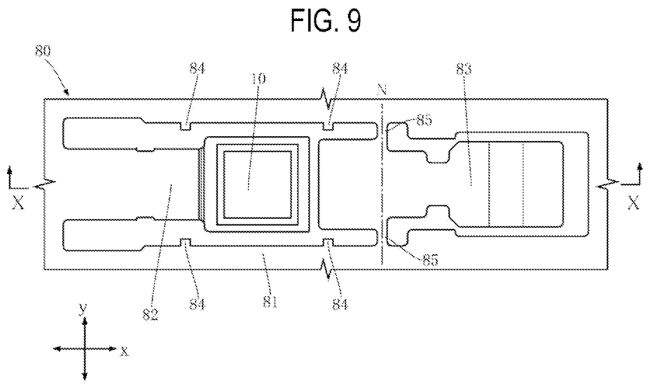

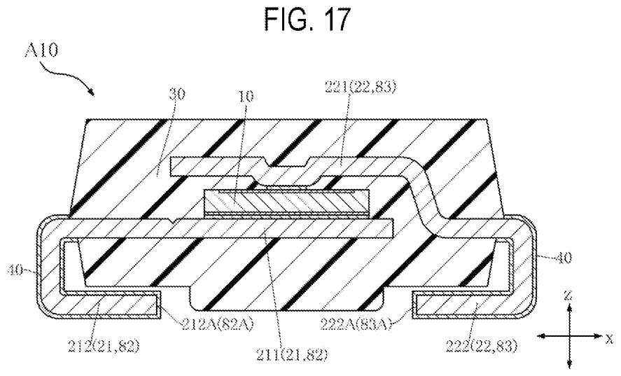

Next, an example of a method of manufacturing the semiconductor device A10 will be described with reference to FIGS. 9 to 17. Herein, a cross-sectional position in FIG. 17 is the same as a cross-sectional position in FIG. 8.

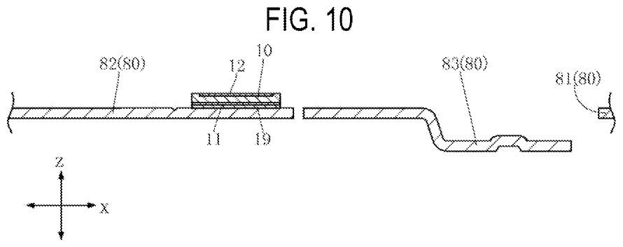

First, as shown in FIGS. 9 and 10, in a lead frame 80 including a frame body 81, a first terminal 82, and a second terminal 83, the first electrode 11 of the semiconductor element 10 is conductively bonded to the first terminal 82. The first terminal 82 and the second terminal 83 are spaced apart from each other in the first direction x. The first terminal 82 is an element that includes the first terminal 21. The second terminal 83 is an element that includes the second terminal 22. The frame body 81 includes a plurality of tie bars and a plurality of section bars and supports each of the first terminal 82 and the second terminal 83. The first electrode 11 of the semiconductor element 10 is conductively bonded to the first terminal 82 by die bonding via the bonding layer 19.

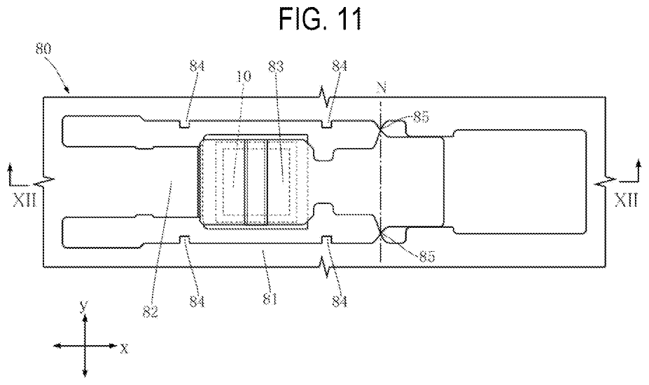

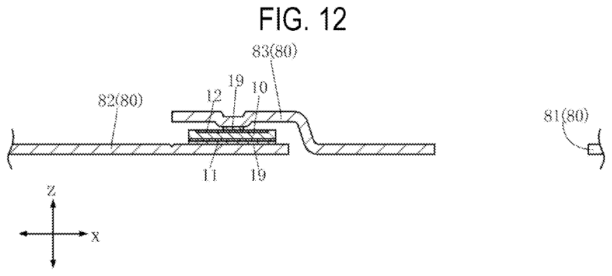

Next, as shown in FIGS. 11 and 12, the second terminal 83 is conductively bonded to the second electrode 12 of the semiconductor element 10. Herein, the lead frame 80 includes two connecting portions 85. The two connecting portions 85 are individually located on both sides of the second terminal 83 in the second direction y. Each of the two connecting portions 85 connects the frame body 81 and the second terminal 83. In this process, after applying the bonding layer 19 to the second electrode 12, the second terminal 83 is inverted around the second direction y while maintaining the state in which the second terminal 83 is connected to the two connecting portions 85. At this time, the second terminal 83 is inverted around an axis N, extending in the second direction y, as a center of rotation. As a result, each of the two connecting portions 85 is twisted. However, the two connecting portions 85 maintain the state in which the frame body 81 and the second terminal 83 are connected.

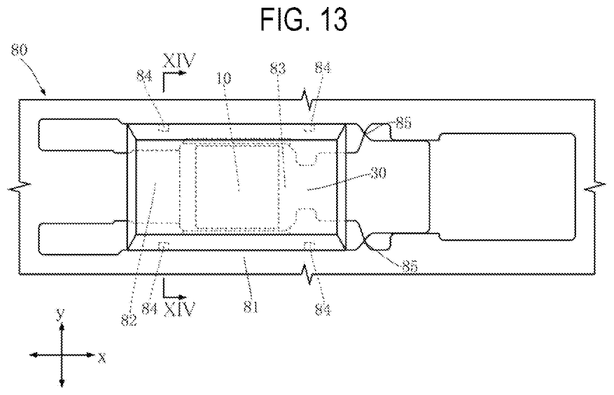

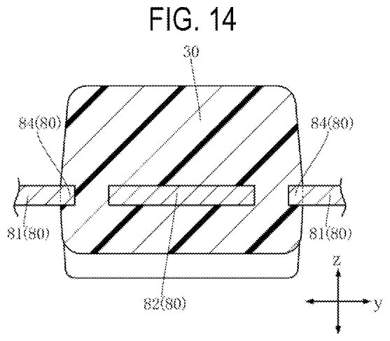

Next, as shown in FIGS. 13 and 14, the sealing resin 30 is formed to cover the semiconductor element 10 and a portion of each of the first terminal 82 and the second terminal 83. The sealing resin 30 is formed by transfer molding. Herein, the lead frame 80 includes a plurality of supports 84 protruding from the lead frame 80 in the second direction y. Each of the plurality of supports 84 is spaced apart from each of the first terminal 82 and the second terminal 83. In this process, the sealing resin 30 is formed to cover each of the plurality of supports 84. As a result, the sealing resin 30 takes a configuration in which it is supported by the plurality of supports 84.

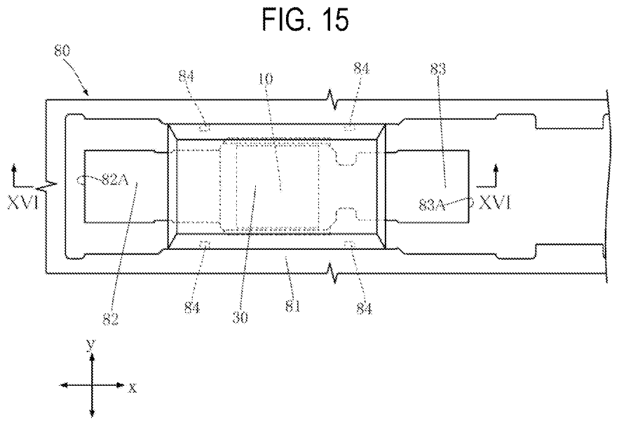

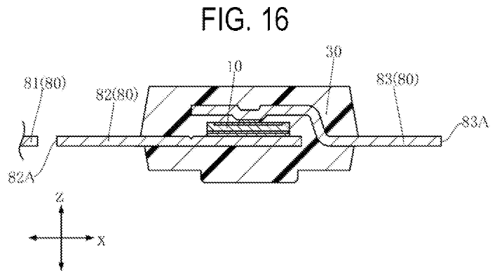

Next, as shown in FIGS. 15 and 16, one side of the first terminal 82 in the first direction x is separated from the frame body 81. In this process, the entirety of each of the first terminal 82 and the second terminal 83 is separated from the frame body 81. Of these, the second terminal 83 is separated from the frame body 81 by cutting each of the two connecting portions 85. At this time, each of the first terminal 82 and the second terminal 83 exposed externally from the sealing resin 30 is formed in a predetermined shape by punching or the like. By undergoing this process, a first end surface 82A facing in the first direction x appears on the first terminal 82. The first end surface 82A corresponds to the first end surface 212A of the first outer portion 212 of the first terminal 21. Additionally, a second end surface 83A facing an opposite side from the first end surface 82A in the first direction x appears on the second terminal 83. The second end surface 83A corresponds to the second end surface 222A of the second outer portion 222 of the second terminal 22.

Next, as shown in FIG. 17, the protective layer 40 is formed to cover a portion of each of the first terminal 82 and the second terminal 83 exposed from the sealing resin 30. The protective layer 40 is formed by immersing each of the first terminal 82 and the second terminal 83 in molten metal containing tin. Apart from this, the protective layer 40 may also be formed by electroless plating, a method of spraying metal particles (excluding electrolytic plating), or the like. As a result, in this process, the entirety of each of the first end surface 82A and the second end surface 83A is covered with the protective layer 40. After forming the protective layer 40, a bending process is performed on the portion of each of the first terminal 82 and the second terminal 83 exposed from the sealing resin 30. Finally, by pulling out the plurality of supports 84 from the sealing resin 30, the semiconductor device A10 may be obtained. In the semiconductor device A10, each of the first concave portion 37 and the second concave portion 38 formed in the sealing resin 30 is a trace that appears when the plurality of supports 84 are pulled out from the sealing resin 30.

Next, operational effects of the semiconductor device A10 will be described.

The semiconductor device A10 includes the first terminal 21, the semiconductor element 10, the sealing resin 30, and the protective layer 40. The first terminal 21 includes the first inner portion 211 and the first outer portion 212. The protective layer 40 covers at least a portion of the first outer portion 212. The first outer portion 212 includes the first end surface 212A facing in the first direction x. The protective layer 40 entirely covers the first end surface 212A. With this configuration, when the semiconductor device A10 is surface-mounted on the wiring board, solder creeps up on the first end surface 212A, so that a contact area of the first outer portion 212 to the solder is further increased. Therefore, according to this configuration, in the semiconductor device A10, it is possible to improve a bonding strength of the semiconductor device A10 to the wiring board.

By the solder creeping up on the first end surface 212A of the first outer portion 212, it becomes easier to visually recognize a state of the solder covering the first outer portion 212. This makes it possible to visually check a mounting state of the semiconductor device A10 on the wiring board.

The semiconductor device A10 further includes the second terminal 22 that is electrically connected to the semiconductor element 10. The second terminal 22 includes the second inner portion 221 and the second outer portion 222. The protective layer 40 covers at least a portion of the second outer portion 222. The second outer portion 222 includes the second end surface 222A facing in the first direction x. The protective layer 40 entirely covers the second end surface 222A. With this configuration, when the semiconductor device A10 is surface-mounted on the wiring board, the solder creeps up on the second end surface 222A, so that a contact area of the second outer portion 222 to the solder is further increased. As a result, it is possible to further improve the bonding strength of the semiconductor device A10 to the wiring board.

The first outer portion 212 of the first terminal 21 protrudes from the first side surface 33 of the sealing resin 30. The second outer portion 222 of the second terminal 22 protrudes from the second side surface 34 of the sealing resin 30. In this case, each of the first terminal 21 and the second terminal 22 is spaced apart from each of the third side surface 35 and the fourth side surface 36 of the sealing resin 30. With this configuration, it is possible to suppress a reduction in creepage distance along a surface of the sealing resin 30 from the first terminal 21 to the second terminal 22. This makes it possible to suppress deterioration of the semiconductor device A10.

The first concave portion 37 recessed from the third side surface 35 and the second concave portion 38 recessed from the fourth side surface 36 are formed in the sealing resin 30. The second concave portion 38 overlaps the first concave portion 37 when viewed in the second direction y. Herein, each of the first concave portion 37 and the second concave portion 38 is a trace that appears when the supports 84 of the lead frame 80 are pulled out from the sealing resin 30 after the process of forming the protective layer 40 shown in FIG. 17 in the manufacturing process of the semiconductor device A10. Therefore, with this configuration, even if the entirety of each of the first terminal 82 and the second terminal 83 is separated from the frame body 81 of the lead frame 80 in the manufacturing process of the semiconductor device A10 (see FIGS. 15 and 16), the sealing resin 30 may be supported by the frame body 81 via the supports 84. Further, in the semiconductor device A10, since the supports 84 exposed from each of the third side surface 35 and the fourth side surface 36 do not remain, it is possible to more effectively suppress a decrease in dielectric breakdown voltage of the semiconductor device A10.

The first concave portion 37 includes the first portion 371 and the second portion 372 that are spaced apart from each other in the first direction x. The second concave portion 38 includes the third portion 381 and the fourth portion 382 that are spaced apart from each other in the first direction x. When viewed in the second direction y, each of the first portion 371 and the third portion 381 overlaps the first inner portion 211 of the first terminal 21. With this configuration, even if the entirety of each of the first terminal 82 and the second terminal 83 is separated from the frame body 81 of the lead frame 80 in the manufacturing process of the semiconductor device A10, the sealing resin 30 may be stably supported by the frame body 81 via the supports 84. The reason for this is that with this configuration, excessive expansion of a distance from a center of gravity of the first terminal 82 to the supports 84 is suppressed.

### Second Embodiment

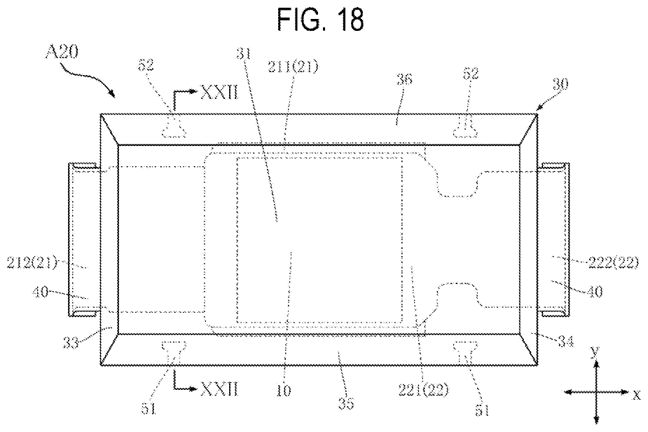

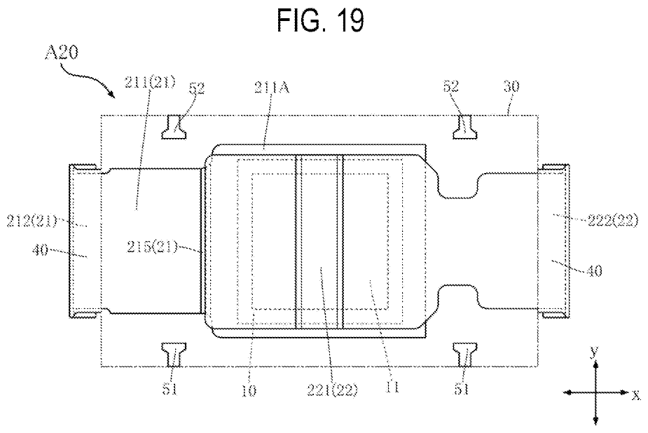

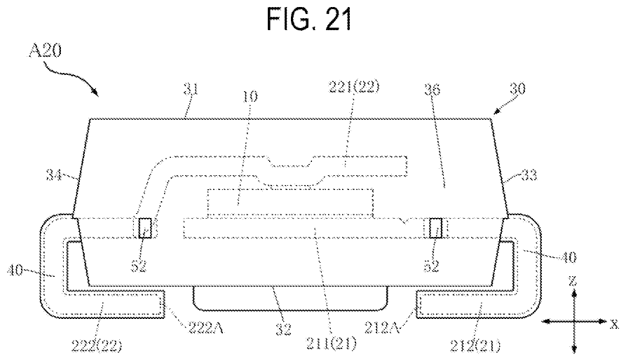

A semiconductor device A20 according to a second embodiment of the present disclosure will be described with reference to FIGS. 18 to 22. In these figures, the same or similar elements as those of the above-described semiconductor device A10 are denoted by the same reference numerals, and explanation thereof will be omitted. Here, in FIG. 19, for the sake of convenience of understanding, the sealing resin 30 is shown to be transparent. In FIG. 19, the transparent sealing resin 30 is indicated by an imaginary line.

The semiconductor device A20 is different from the semiconductor device A10 in that the former further includes two first support pins 51 and two second support pins 52.

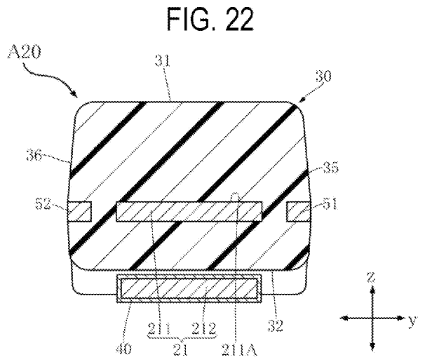

As shown in FIGS. 18 and 22, each of the two first support pins 51 and the two second support pins 52 is accommodated in the sealing resin 30. Each of the two first support pins 51 and the two second support pins 52 is obtained from the same lead frame 80 (see FIG. 9) as the first terminal 21 and the second terminal 22. Each of the two first support pins 51 and the two second support pins 52 contains copper.

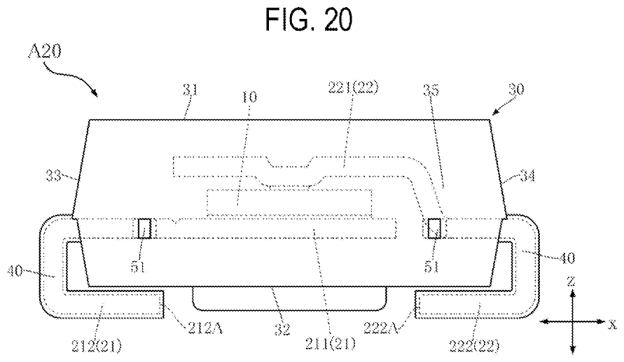

As shown in FIG. 19, the two first support pins 51 are spaced apart from each of the first terminal 21 and the second terminal 22 and are also spaced apart from each other in the first direction x. As shown in FIG. 20, each of the two first support pins 51 is externally exposed from the third side surface 35 of the sealing resin 30. When viewed in the third direction z, in each of the two first support pins 51, a portion located opposite from a portion exposed from the third side surface 35 in the second direction y has a shape expanding in the first direction x. Each of the two first support pins 51 corresponds to any one of the plurality of supports 84 of the lead frame 80 shown in FIG. 9. In manufacturing the semiconductor device A20, each of the two first support pins 51 is separated from the frame body 81 of the lead frame 80 in the process shown in FIG. 17.

As shown in FIG. 19, the two second support pins 52 are spaced apart from each of the first terminal 21 and the second terminal 22 and are also spaced apart from each other in the first direction x. The two second support pins 52 are located opposite to the two first support pins 51 with respect to the first terminal 21 and the second terminal 22 in the second direction y. Each of the two second support pins 52 is externally exposed from the fourth side surface 36 of the sealing resin 30. When viewed in the third direction z, in each of the two second support pins 52, a portion located opposite from a portion exposed from the fourth side surface 36 in the second direction y has a shape expanding in the first direction x. Each of the two second support pins 52 corresponds to any one of the plurality of supports 84 of the lead frame 80 shown in FIG. 9. In manufacturing the semiconductor device A20, each of the two second support pins 52 is separated from the frame body 81 of the lead frame 80 in the process shown in FIG. 17.

Next, operational effects of the semiconductor device A20 will be described.

The semiconductor device A20 includes the first terminal 21, the semiconductor element 10, the sealing resin 30, and the protective layer 40. The first terminal 21 includes the first inner portion 211 and the first outer portion 212. The protective layer 40 covers at least a portion of the first outer portion 212. The first outer portion 212 includes the first end surface 212A facing in the first direction x. The protective layer 40 entirely covers the first end surface 212A. Therefore, according to this configuration, in the semiconductor device A20 as well, it is possible to improve a bonding strength of the semiconductor device A20 to the wiring board. Further, the semiconductor device A20 includes same configurations as those of the semiconductor device A10, so that the same effects as those of the semiconductor device A10 may be achieved.

The semiconductor device A20 further includes the first support pin 51 and the second support pin 52, each of which is accommodated in the sealing resin 30. The first support pin 51 is spaced apart from the first terminal 21 and the second terminal 22 and is externally exposed from the third side surface 35 of the sealing resin 30. The second support pin 52 is spaced apart from the first terminal 21 and the second terminal 22 and is externally exposed from the fourth side surface 36 of the sealing resin 30. Herein, each of the first support pin 51 and the second support pin 52 corresponds to the support 84 of the lead frame 80 shown in FIG. 9. With this configuration, even if the entirety of each of the first terminal 82 and the second terminal 83 is separated from the frame body 81 of the lead frame 80 in the manufacturing process of the semiconductor device A20 (see FIGS. 15 and 16), the sealing resin 30 may be supported by the frame body 81 via the supports 84. Further, since each of the first support pin 51 and the second support pin 52 is spaced apart from each of the first terminal 21 and the second terminal 22, it is possible to suppress a decrease in dielectric breakdown voltage of the semiconductor device A20.

When viewed in the third direction z, in each of the first support pin 51 and the second support pin 52, the portion located opposite from the portion exposed from the sealing resin 30 in the second direction y has a shape expanding in the first direction x. With this configuration, when the entirety of each of the first terminal 82 and the second terminal 83 is separated from the frame body 81 of the lead frame 80 in the manufacturing process of the semiconductor device A20 (see FIGS. 15 and 16), it is possible to more reliably prevent the sealing resin 30 from falling off from the frame body 81.

### Third Embodiment

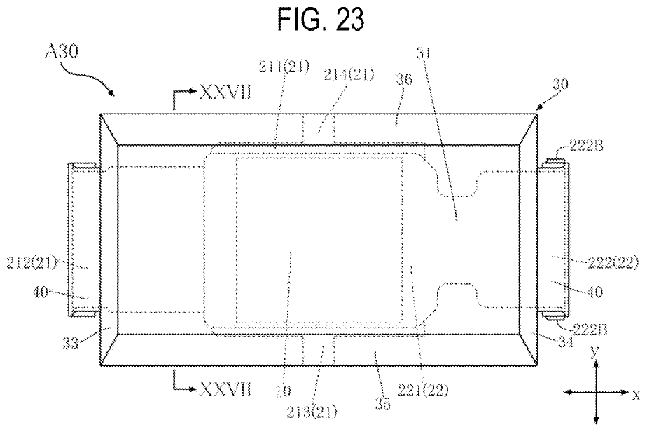

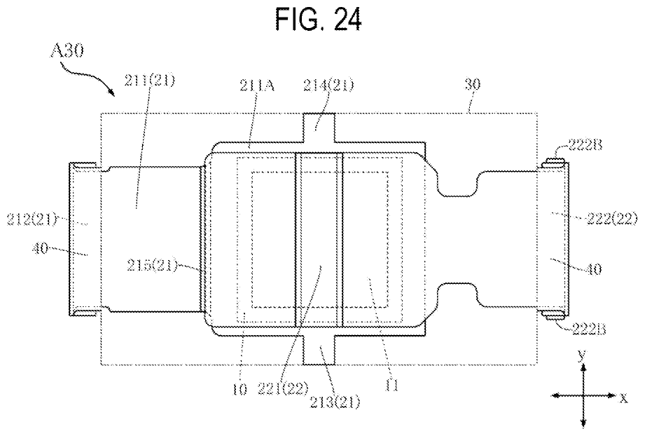

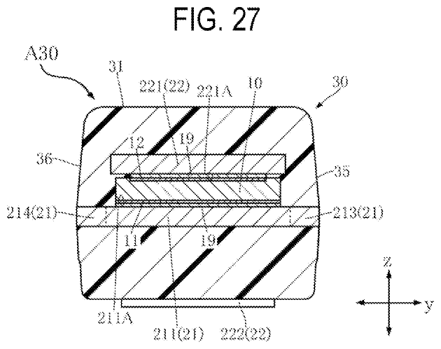

A semiconductor device A30 according to a third embodiment of the present disclosure will be described with reference to FIGS. 23 to 27. In these figures, the same or similar elements as those of the above-described semiconductor device A10 are denoted by the same reference numerals, and explanation thereof will be omitted. Here, in FIG. 24, for the sake of convenience of understanding, the sealing resin 30 is shown to be transparent. In FIG. 24, the transparent sealing resin 30 is indicated by an imaginary line.

The semiconductor device A30 is different from the semiconductor device A10 in terms of configurations of the first terminal 21, the second terminal 22, and the sealing resin 30.

As shown in FIGS. 23, 24, and 27, the first terminal 21 includes a first hanger 213 and a second hanger 214. Each of the first hanger 213 and the second hanger 214 is accommodated in the sealing resin 30.

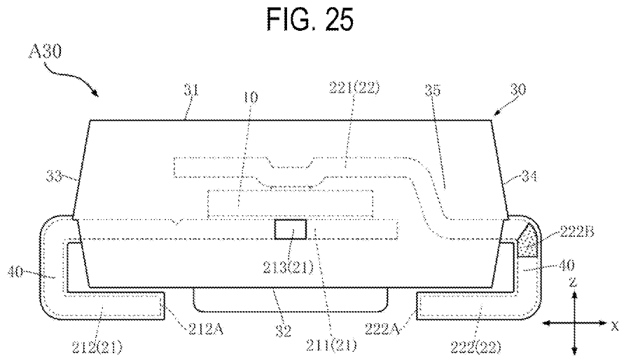

As shown in FIG. 24, the first hanger 213 is connected to one side of the first inner portion 211 of the first terminal 21 in the second direction y. The first hanger 213 extends in the second direction y. As shown in FIG. 25, the first hanger 213 is externally exposed from the third side surface 35 of the sealing resin 30. The first hanger 213 corresponds to any one of the plurality of supports 84 of the lead frame 80 shown in FIG. 9. In manufacturing the semiconductor device A30, the first hanger 213 is separated from the frame body 81 of the lead frame 80 in the process shown in FIG. 17.

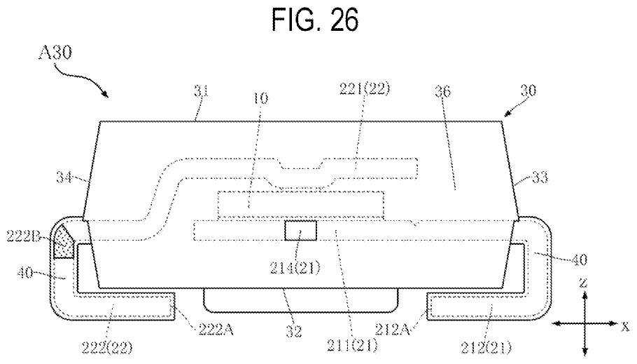

As shown in FIG. 24, the second hanger 214 is located opposite to the first hanger 213 with respect to the first inner portion 211 of the first terminal 21 in the second direction y and is connected to the first inner portion 211. The second hanger 214 extends in the second direction y. As shown in FIG. 26, the second hanger 214 is externally exposed from the fourth side surface 36 of the sealing resin 30. The second hanger 214 corresponds to any one of the plurality of supports 84 of the lead frame 80 shown in FIG. 9. In manufacturing the semiconductor device A30, the second hanger 214 is separated from the frame body 81 of the lead frame 80 in the process shown in FIG. 17.

As shown in FIGS. 23 to 26, two cut surfaces 222B facing opposite to each other in the second direction y are formed at the second outer portion 222 of the second terminal 22. Each of the two cut surfaces 222B is externally exposed from the protective layer 40. Surface roughness of each of the two cut surfaces 222B is greater than surface roughness of the bonding surface 221A of the second inner portion 221 of the second terminal 22.

In the semiconductor device A30, the first concave portion 37 and the second concave portion 38 are not formed in the sealing resin 30.

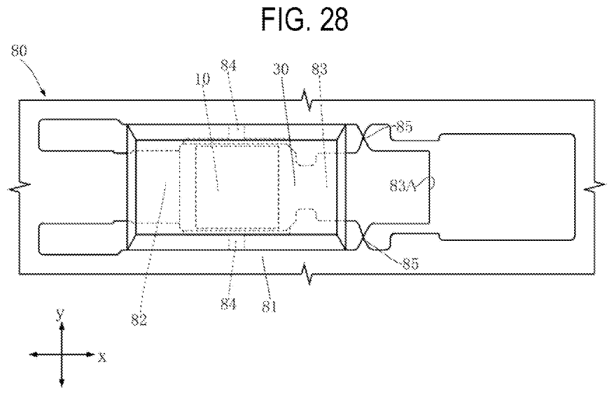

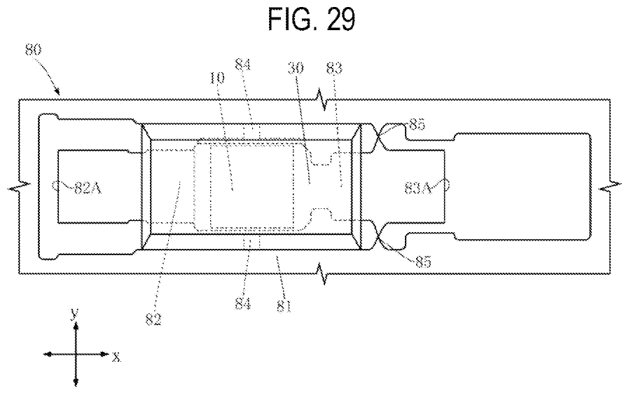

Next, in an example of a method of manufacturing the semiconductor device A30, features that are different from the example of the method of manufacturing the semiconductor device A10 will be described based on FIGS. 28 and 29.

The method of manufacturing the semiconductor device A30 is different from the method of manufacturing the semiconductor device A10 in terms of the configuration of the lead frame 80. As shown in FIGS. 28 and 29, each of the plurality of supports 84 is connected to the first terminal 82.

FIG. 28 is a diagram illustrating a process of forming the sealing resin 30, which corresponds to FIG. 13 illustrating the manufacturing process of the semiconductor device A10. In manufacturing the semiconductor device A30, the second end surface 83A is made to appear on the second terminal 83 until a process before the process shown in FIG. 28.

FIG. 29 is a diagram illustrating a process of separating one side of the first terminal 82 in the first direction x from the frame body 81 of the lead frame 80, which corresponds to FIG. 15 illustrating the manufacturing process of the semiconductor device A10. Through this process, the first end surface 82A appears on the first terminal 82. In the process shown in FIG. 29, the first terminal 82 is supported by the frame body 81 of the lead frame 80 via the plurality of supports 84. The second terminal 83 is supported by the frame body 81 via the two connecting portions 85. Therefore, in the process shown in FIG. 29, unlike the manufacturing process of the semiconductor device A10, each of the first terminal 82 and the second terminal 83 is not entirely separated from the frame body 81.

Next, operational effects of the semiconductor device A30 will be described.

The semiconductor device A30 includes the first terminal 21, the semiconductor element 10, the sealing resin 30, and the protective layer 40. The first terminal 21 includes the first inner portion 211 and the first outer portion 212. The protective layer 40 covers at least a portion of the first outer portion 212. The first outer portion 212 includes the first end surface 212A facing in the first direction x. The protective layer 40 covers the entire first end surface 212A. Therefore, according to this configuration, in the semiconductor device A30 as well, it is possible to improve a bonding strength of the semiconductor device A30 to the wiring board. Further, the semiconductor device A30 includes same configurations as configurations of the semiconductor device A10, so that the same effects as those of the semiconductor device A10 may be achieved.

In the semiconductor device A30, the first terminal 21 includes the first hanger 213 and the second hanger 214. The first hanger 213 is connected to the first inner portion 211 and is externally exposed from the third side surface 35 of the sealing resin 30. The second hanger 214 is connected to the first inner portion 211 and is externally exposed from the fourth side surface 36 of the sealing resin 30. Herein, each of the first hanger 213 and the second hanger 214 corresponds to the support 84 of the lead frame 80 shown in FIG. 9. With this configuration, even if a portion of the first terminal 82 is separated from the frame body 81 of the lead frame 80 in the manufacturing process of the semiconductor device A30 (see FIG. 29), the sealing resin 30 may be supported by the frame body 81 via the support 84. Further, in the process of forming the protective layer 40 in the manufacturing process of the semiconductor device A30, the protective layer 40 that covers the entirety of a portion of the first terminal 82 (including the entire first end surface 82A) exposed from the sealing resin 30 may be formed by electrolytic plating using the frame body 81 and the support 84 as a conductive path.

In the process of separating a portion of the first terminal 82 from the frame body 81 of the lead frame 80 in the manufacturing process of the semiconductor device A30 (see FIG. 29), the protective layer 40 may be formed while the second terminal 83 is being supported by the frame body 81 via the two connecting portions 85. With this method, the protective layer 40 that covers the entirety of a portion of the second terminal 83 (including the entire second end surface 83A, but excluding an interface between the second terminal 83 and the two connecting portions 85) exposed from the sealing resin 30 may be formed by electrolytic plating using the frame body 81 and the two connecting portions 85 as a conductive path. Here, in the semiconductor device A30, the two cut surfaces 222B formed at the second outer portion 222 of the second terminal 22 are a trace obtained by cutting the two connecting portions 85 after forming the protective layer 40 covering the second terminal 83 by the electrolytic plating.

### Fourth Embodiment

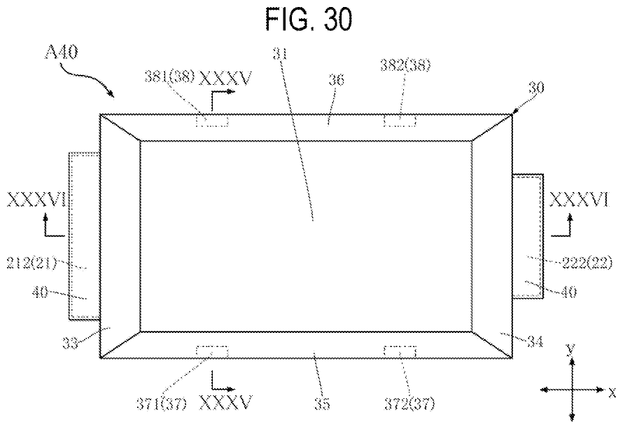

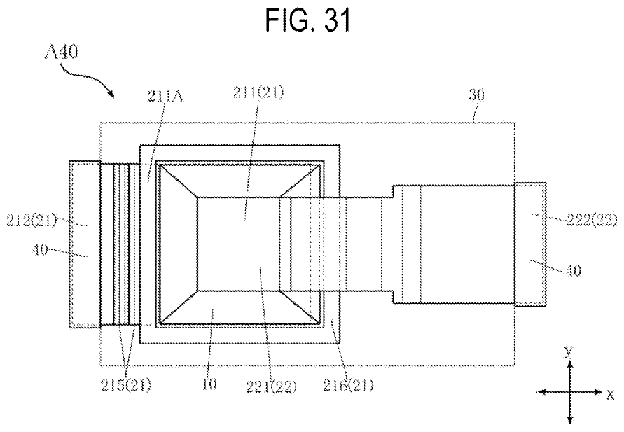

A semiconductor device A40 according to a fourth embodiment of the present disclosure will be described with reference to FIGS. 30 to 36. In these figures, the same or similar elements as those of the above-described semiconductor device A10 are denoted by the same reference numerals, and explanation thereof will be omitted. Here, in FIG. 31, for the sake of convenience of understanding, the sealing resin 30 is shown to be transparent. In FIG. 31, the transparent sealing resin 30 is indicated by an imaginary line.

The semiconductor device A40 is different from the semiconductor device A10 in terms of configurations of the first terminal 21, the second terminal 22, and the sealing resin 30. Further, the semiconductor device A40 is different from the semiconductor device A10 in terms of a shape of the semiconductor element 10.

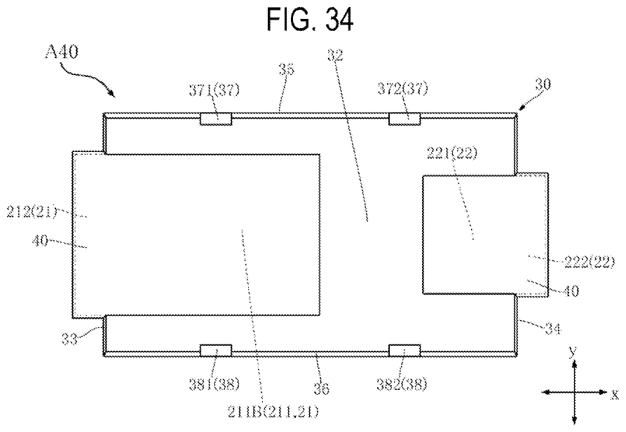

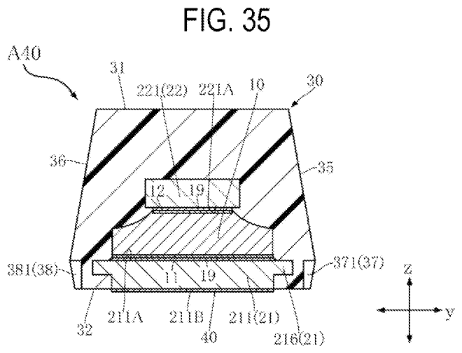

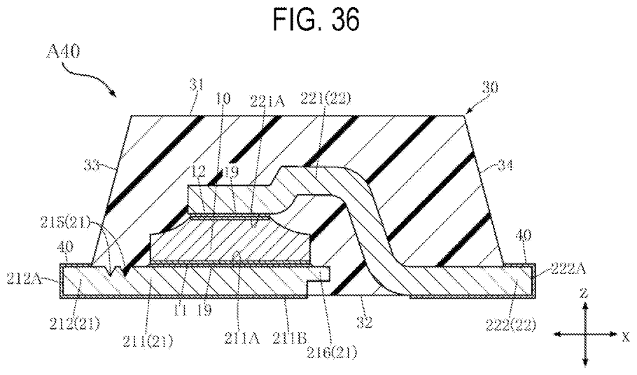

As shown in FIGS. 35 and 36, the first inner portion 211 of the first terminal 21 includes an installation surface 211B. The installation surface 211B faces an opposite side from the mounting surface 211A in the third direction z. As shown in FIG. 34, the installation surface 211B is exposed from the bottom surface 32 of the sealing resin 30. The installation surface 211B is covered with the protective layer 40.

As shown in FIGS. 31, 35, and 36, the first terminal 21 includes an eaves portion 216. The eaves portion 216 is flush with the mounting surface 211A of the first inner portion 211 of the first terminal 21. A dimension of the eaves portion 216 in the third direction z is smaller than a dimension of the first inner portion 211 in the third direction z. The eaves portion 216 is sandwiched by the sealing resin 30 from both sides in the third direction z.

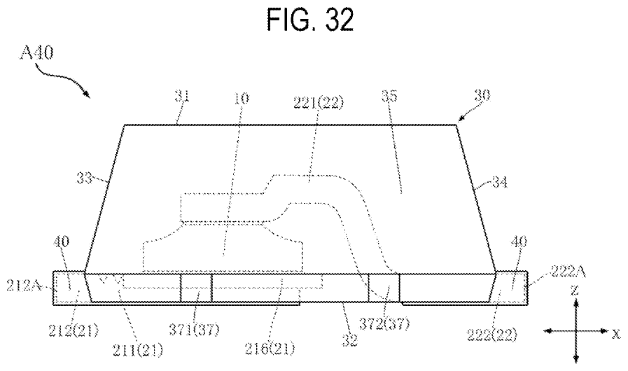

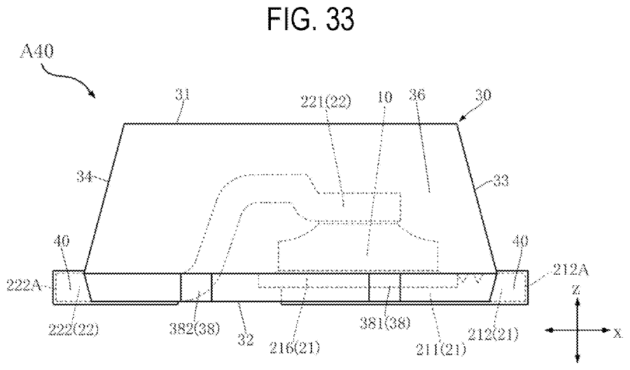

As shown in FIGS. 32 and 33, the first end surface 212A of the first outer portion 212 of the first terminal 21 faces a same side as the first side surface 33 of the sealing resin 30 in the first direction x. The first outer portion 212 of the first terminal 21 is not bent around the second direction y, unlike the case of the semiconductor device A10.

As shown in FIG. 34, the second inner portion 221 of the second terminal 22 is exposed from the bottom surface 32 of the sealing resin 30. A portion of the second inner portion 221 exposed from the bottom surface 32 is covered with the protective layer 40.

As shown in FIGS. 32 and 33, the second end surface 222A of the second outer portion 222 of the second terminal 22 faces a same side as the second side surface 34 of the sealing resin 30 in the first direction x. The second outer portion 222 of the second terminal 22 is not bent around the second direction y, unlike the case of the semiconductor device A10.

As shown in FIGS. 32, 34, and 35, the first concave portion 37 is recessed from each of the bottom surface 32 and the third side surface 35 of the sealing resin 30. As shown in FIGS. 33 to 35, the second concave portion 38 is recessed from each of the bottom surface 32 and the fourth side surface 36 of the sealing resin 30.

Next, operational effects of the semiconductor device A40 will be described.

The semiconductor device A40 includes the first terminal 21, the semiconductor element 10, the sealing resin 30, and the protective layer 40. The first terminal 21 includes the first inner portion 211 and the first outer portion 212. The protective layer 40 covers at least a portion of the first outer portion 212. The first outer portion 212 includes the first end surface 212A facing in the first direction x. The protective layer 40 covers the entire first end surface 212A. Therefore, according to this configuration, in the semiconductor device A40 as well, it is possible to improve a bonding strength of the semiconductor device A40 to the wiring board. Further, the semiconductor device A40 includes same configurations as configurations of the semiconductor device A10, so that the same effects as those of the semiconductor device A10 may be achieved.

The present disclosure is not limited to the above-described embodiments. The specific configuration of each part of the present disclosure may be modified in design in various ways.

Herein, each of the embodiments according to the present disclosure is a semiconductor device of a surface mount package. In addition, techniques according to the present disclosure may also be applied to semiconductor devices whose package forms are TO (Transistor Outline) or DIP (Dual Inline Package). TO and DIP are generally through-hole-mounted on a wiring board, but in some cases, each of the first terminal 21 and the second terminal 22 protruding from the sealing resin 30 may be bent and surface-mounted. In these cases, by applying the techniques of the present disclosure to a semiconductor device in each of the TO and DIP package forms, the semiconductor device exhibits the same effects as the embodiments of the present disclosure.

The present disclosure includes embodiments described in the following supplementary notes.

### Supplementary Note 1

A semiconductor device including:
a first terminal;
a semiconductor element electrically connected to the first terminal;
a sealing resin that covers the semiconductor element; and
a protective layer that covers a portion of the first terminal and has conductivity,
wherein the first terminal includes a first inner portion at least partially covered with the sealing resin, and a first outer portion connected to the first inner portion and protruding from the sealing resin,
wherein the protective layer covers at least a portion of the first outer portion,
wherein the first outer portion includes a first end surface facing in a first direction, and
wherein the protective layer entirely covers the first end surface.

### Supplementary Note 2

The semiconductor device of Supplementary Note 1, wherein the sealing resin includes a first side surface facing in the first direction, and
wherein the first outer portion protrudes from the first side surface.

### Supplementary Note 3

The semiconductor device of Supplementary Note 2, further including: a second terminal electrically connected to the semiconductor element,
wherein the sealing resin includes a second side surface facing opposite from the first side surface in the first direction,
wherein the second terminal includes a second inner portion covered with the sealing resin, and a second outer portion connected to the second inner portion and protruding from the second side surface,
wherein the protective layer covers at least a portion of the second outer portion,
wherein the second outer portion includes a second end surface facing opposite from the first end surface in the first direction, and
wherein the protective layer entirely covers the second end surface.

### Supplementary Note 4

The semiconductor device of Supplementary Note 3, wherein the sealing resin includes a third side surface and a fourth side surface that face opposite from each other in a second direction perpendicular to the first direction, and
wherein each of the first terminal and the second terminal is spaced apart from each of the third side surface and the fourth side surface.

### Supplementary Note 5

The semiconductor device of Supplementary Note 4, wherein the semiconductor element includes a first electrode and a second electrode that are located opposite from each other in a third direction perpendicular to each of the first direction and the second direction,
wherein the first electrode is conductively bonded to the first inner portion, and
wherein the second electrode is conductively bonded to the second inner portion.

### Supplementary Note 6

The semiconductor device of Supplementary Note 5, wherein a first concave portion recessed from the third side surface is formed in the sealing resin.

### Supplementary Note 7

The semiconductor device of Supplementary Note 6, wherein a second concave portion recessed from the fourth side surface is formed in the sealing resin, and
wherein the second concave portion overlaps the first concave portion when viewed in the second direction.

### Supplementary Note 8

The semiconductor device of Supplementary Note 7, wherein the first concave portion includes a first portion and a second portion that are spaced apart from each other in the first direction,
wherein the second concave portion includes a third portion and a fourth portion that are spaced apart from each other in the first direction, and
wherein each of the first portion and the third portion overlaps the first inner portion when viewed in the second direction.

### Supplementary Note 9

The semiconductor device of Supplementary Note 5, further including: a first support pin and a second support pin that are each accommodated in the sealing resin,
wherein the first support pin is spaced apart from each of the first terminal and the second terminal and is externally exposed from the third side surface, and
wherein the second support pin is spaced apart from each of the first terminal and the second terminal and is externally exposed from the fourth side surface.

### Supplementary Note 10

The semiconductor device of Supplementary Note 5, wherein the first terminal includes a first hanger connected to the first inner portion and accommodated in the sealing resin, and
wherein the first hanger is externally exposed from the third side surface.

### Supplementary Note 11

The semiconductor device of Supplementary Note 10, wherein the first terminal includes a second hanger connected to the first inner portion and accommodated in the sealing resin,
wherein the second hanger is located opposite to the first hanger with respect to the first inner portion in the second direction, and
wherein the second hanger is externally exposed from the fourth side surface.

### Supplementary Note 12

The semiconductor device of Supplementary Note 11, wherein two cut surfaces facing opposite from each other in the second direction are formed at the second outer portion,
wherein the second inner portion includes a bonding surface facing the second electrode, and
wherein surface roughness of each of the two cut surfaces is greater than surface roughness of the bonding surface.

### Supplementary Note 13

The semiconductor device of any one of Supplementary Note 6 to 12, wherein the first end surface faces opposite from the first side surface in the first direction, and
wherein the first inner portion is entirely covered with the sealing resin.

### Supplementary Note 14

The semiconductor device of Supplementary Note 7 or 8, wherein the first end surface faces a same side as the first side surface in the first direction.

### Supplementary Note 15

The semiconductor device of Supplementary Note 14, wherein the first inner portion includes a mounting surface and an installation surface facing opposite from each other in the third direction,
wherein the first electrode is conductively bonded to the mounting surface, and wherein the installation surface is exposed from the sealing resin.

### Supplementary Note 16

The semiconductor device of Supplementary Note 15, wherein the sealing resin includes a bottom surface facing a same side as the installation surface in the third direction, and
wherein each of the first concave portion and the second concave portion is recessed from the bottom surface.

### Supplementary Note 17

A method of manufacturing a semiconductor device, including:
in a lead frame including a first terminal and a second terminal spaced apart from each other in a first direction, and a frame body that supports each of the first terminal and the second terminal, conductively bonding a semiconductor element to the first terminal;
conductively bonding the second terminal to the semiconductor element;
forming a sealing resin that covers the semiconductor element and a portion of each of the first terminal and the second terminal;
separating one side of the first terminal in the first direction from the frame body; and
forming a protective layer that covers a portion of each of the first terminal and the second terminal which is exposed from the sealing resin,
wherein the lead frame includes a support that protrudes from the frame body in a second direction perpendicular to the first direction,
wherein in the forming the sealing resin, the sealing resin is formed to cover the support, and
wherein the forming the protective layer is performed after the separating the one side of the first terminal in the first direction from the frame body.

### Supplementary Note 18

The method of Supplementary Note 17, wherein the lead frame includes two connecting portions located individually on both sides of the second terminal in the second direction,
wherein each of the two connecting portions connects the frame body and the second terminal, and
wherein in the conductively bonding the second terminal, the second terminal is inverted around the second direction in a state of being connected to the two connecting portions.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first terminal;
a semiconductor element electrically connected to the first terminal;
a sealing resin that covers the semiconductor element; and
a protective layer that covers a portion of the first terminal and has conductivity,
wherein the first terminal includes a first inner portion at least partially covered with the sealing resin, and a first outer portion connected to the first inner portion and protruding from the sealing resin,
wherein the protective layer covers at least a portion of the first outer portion,
wherein the first outer portion includes a first end surface facing in a first direction, and
wherein the protective layer entirely covers the first end surface.

2. The semiconductor device of claim 1, wherein the sealing resin includes a first side surface facing in the first direction, and
wherein the first outer portion protrudes from the first side surface.

3. The semiconductor device of claim 2, further comprising: a second terminal electrically connected to the semiconductor element,
wherein the sealing resin includes a second side surface facing opposite from the first side surface in the first direction,
wherein the second terminal includes a second inner portion covered with the sealing resin, and a second outer portion connected to the second inner portion and protruding from the second side surface,
wherein the protective layer covers at least a portion of the second outer portion,
wherein the second outer portion includes a second end surface facing opposite from the first end surface in the first direction, and
wherein the protective layer entirely covers the second end surface.

4. The semiconductor device of claim 3, wherein the sealing resin includes a third side surface and a fourth side surface that face opposite from each other in a second direction perpendicular to the first direction, and
wherein each of the first terminal and the second terminal is spaced apart from each of the third side surface and the fourth side surface.

5. The semiconductor device of claim 4, wherein the semiconductor element includes a first electrode and a second electrode that are located opposite from each other in a third direction perpendicular to each of the first direction and the second direction,
wherein the first electrode is conductively bonded to the first inner portion, and
wherein the second electrode is conductively bonded to the second inner portion.

6. The semiconductor device of claim 5, wherein a first concave portion recessed from the third side surface is formed in the sealing resin.

7. The semiconductor device of claim 6, wherein a second concave portion recessed from the fourth side surface is formed in the sealing resin, and
wherein the second concave portion overlaps the first concave portion when viewed in the second direction.

8. The semiconductor device of claim 7, wherein the first concave portion includes a first portion and a second portion that are spaced apart from each other in the first direction,
wherein the second concave portion includes a third portion and a fourth portion that are spaced apart from each other in the first direction, and
wherein each of the first portion and the third portion overlaps the first inner portion when viewed in the second direction.

9. The semiconductor device of claim 5, further comprising: a first support pin and a second support pin that are each accommodated in the sealing resin,
wherein the first support pin is spaced apart from each of the first terminal and the second terminal and is externally exposed from the third side surface, and
wherein the second support pin is spaced apart from each of the first terminal and the second terminal and is externally exposed from the fourth side surface.

10. The semiconductor device of claim 5, wherein the first terminal includes a first hanger connected to the first inner portion and accommodated in the sealing resin, and
wherein the first hanger is externally exposed from the third side surface.

11. The semiconductor device of claim 10, wherein the first terminal includes a second hanger connected to the first inner portion and accommodated in the sealing resin,
wherein the second hanger is located opposite to the first hanger with respect to the first inner portion in the second direction, and
wherein the second hanger is externally exposed from the fourth side surface.

12. The semiconductor device of claim 11, wherein two cut surfaces facing opposite from each other in the second direction are formed at the second outer portion,
wherein the second inner portion includes a bonding surface facing the second electrode, and
wherein surface roughness of each of the two cut surfaces is greater than surface roughness of the bonding surface.

13. The semiconductor device of claim 6, wherein the first end surface faces opposite from the first side surface in the first direction, and
wherein the first inner portion is entirely covered with the sealing resin.

14. The semiconductor device of claim 7, wherein the first end surface faces a same side as the first side surface in the first direction.

15. The semiconductor device of claim 14, wherein the first inner portion includes a mounting surface and an installation surface facing opposite from each other in the third direction,
wherein the first electrode is conductively bonded to the mounting surface, and
wherein the installation surface is exposed from the sealing resin.

16. The semiconductor device of claim 15, wherein the sealing resin includes a bottom surface facing a same side as the installation surface in the third direction, and
wherein each of the first concave portion and the second concave portion is recessed from the bottom surface.

17. A method of manufacturing a semiconductor device, comprising:
in a lead frame including a first terminal and a second terminal spaced apart from each other in a first direction, and a frame body that supports each of the first terminal and the second terminal, conductively bonding a semiconductor element to the first terminal;
conductively bonding the second terminal to the semiconductor element;
forming a sealing resin that covers the semiconductor element and a portion of each of the first terminal and the second terminal;
separating one side of the first terminal in the first direction from the frame body; and
forming a protective layer that covers a portion of each of the first terminal and the second terminal which is exposed from the sealing resin,
wherein the lead frame includes a support that protrudes from the frame body in a second direction perpendicular to the first direction,
wherein in the forming the sealing resin, the sealing resin is formed to cover the support, and
wherein the forming the protective layer is performed after the separating the one side of the first terminal in the first direction from the frame body.

18. The method of claim 17, wherein the lead frame includes two connecting portions located individually on both sides of the second terminal in the second direction,
wherein each of the two connecting portions connects the frame body and the second terminal, and
wherein in the conductively bonding the second terminal, the second terminal is inverted around the second direction in a state of being connected to the two connecting portions.
